(19) United States
(12) Patent Application Publication
(10) Pub. No.: US 2009/0206889 A1
(43) Pub. Date: Aug. 20, 2009

(54) Method and Apparatus for Controlling Power Surge in an Integrated Circuit

(75) Inventors: Richard Reohr, Hillsboro, OR (US); Richard Wiita, Wyoming, MN (US)

Correspondence Address: GEORGE A LEONE, SR;CITADEL PATENT LAW, 1117 BROADWAY, SUITE 401, TACOMA, WA, 98402, US

(73) Assignee: MathStar, Inc., Hillsboro, OR (US)

(21) Appl. No.: 12/032,503

(22) Filed: Feb. 15, 2008

(51) Int. Cl. H03B 19/00

(52) U.S. Cl. 327/113

(57) ABSTRACT

A method for ramping a high-speed clock to control power surge in an integrated circuit when transitioning from a low power holdstate to an operational state where the integrated circuit includes selected logic circuits adapted to be maintained in the holdstate. A core clock signal including a plurality of core clock pulses is gated with a ramping signal. The ramping signal includes a series of staged signals having gating pulses. Each staged signal is separated by a ramp interval, where the series of staged signals successively enables increasing numbers of clocking pulses from the core clock signal to be transmitted to a holdstate output until a predetermined operational core clock frequency is transmitted to the holdstate output bringing the integrated circuit to the operational state.

### TECHNICAL FIELD

The present invention relates to integrated circuits, and more particularly, to an apparatus and method for ramping a high-speed clock to control power surge in an integrated circuit.

### BACKGROUND

A field-programmable object array or FPOA is a medium grain architecture comprising highly optimized silicon objects that are individually programmed and synchronously interconnected via high performance parallel communications structures, permitting the user to configure the device to implement a variety of very high performance algorithms. The high level functions available in the objects combined with the unique interconnect structure enables performance superior to existing field programmable solutions while maintaining and enhancing the flexibility.

A series of FPOA devices manufactured by Mathstar, Inc. of Portland, Oreg., include an FPOA architecture providing a massively parallel, high-performance computation fabric consisting of hundreds of processing elements called Silicon Objects. Each Silicon Object is programmed individually and acts autonomously. Each ALU Silicon Object can be programmed from a choice of instructions. These objects are surrounded by additional Internal RAM (IRAM) blocks, memory controllers and a rich mix of high-performance I/O. Communication between adjacent Silicon Objects is accomplished via nearest neighbor interconnects. In a typical FPOA communication planes operate around 1 GHz, are independently configurable and provide deterministic timing.

When the FPOA circuitry is not actively operating FPOA devices may be maintained in a holdstate to reduce power consumption. In transitioning from the holdstate to an operational state, typical current consumption by an FPOA increases rapidly to full power. In previous FPOA designs this transition was made instantaneously, by gating the device clock toggling at full speed. While such devices were a significant and welcome advance, it was felt that even greater advances could be made with improved transitional current control from very low current to full operational current flow (around 50 amps or more in some devices).

As a result, later devices were designed to split current consumption surges into two half steps while transitioning from the holdstate to an operational state. Illustrated in FIG. 1 is a curve representing integrated circuit current consumption 20 as a function of time during a transition from a holdstate to an operational state in a previous design. The transition was segmented into three time periods, namely, configuration loading 50, initialization duration 60 and normal operation 70. Voltage curve 22 shows concomitant effects 10 of the two-step current surge on the power supply voltage, V_{cc}. After configuration loading, the first step in the two-step current surge corresponds to starting the core clock, while the second step corresponds to initialization of operational circuits. While delaying initialization as the core clock comes up to speed results in faster circuit operation, it also may cause a proportionally higher current surge. Thus there is a tradeoff between early initialization and power transition effects.

Current surge effects have also been addressed for transitioning other types of integrated circuits, like CPUs. In U.S. Pat. No. 7,281,149 issued Oct. 9, 2007 to Atkinson, a CPU stopclock signal is used to generate a controlled transitioning signal. This stopclock signal approach does not provide a sufficiently rapid method using a ramped rate of clock modulation better suited to logic circuitry found in devices like FPOAs.

Before the present disclosure there was a need for a way to allow a high speed clock to ramp up in a rapid controlled manner without using complex circuitry like multiple phased lock loop devices. The present disclosure provides a new, novel and surprisingly effective method for controlling power surge in an integrated circuit. Using the techniques disclosed a significant reduction of circuitry complexity and cost can be achieved by providing a device that can operate at a lower voltage and still maintain its configuration.

### BRIEF SUMMARY OF THE DISCLOSURE

A method for ramping a high-speed clock to control power surge in an integrated circuit when transitioning from a low power holdstate to an operational state where the integrated circuit includes selected logic circuits adapted to be maintained in the holdstate. A core clock signal including a plurality of core clock pulses is gated with a ramping signal. The ramping signal includes a series of staged signals having gating pulses. Each staged signal is separated by a ramp interval, where the series of staged signals successively enables increasing numbers of clocking pulses from the core clock signal to be transmitted to a holdstate output until a predetermined operational core clock frequency is transmitted to the holdstate output bringing the integrated circuit to the operational state.

### BRIEF DESCRIPTION OF THE DRAWINGS

FIG. 1 graphically shows a prior art method of clock gating for a semiconductor integrated circuit device while switching from a holdstate to an operational state.

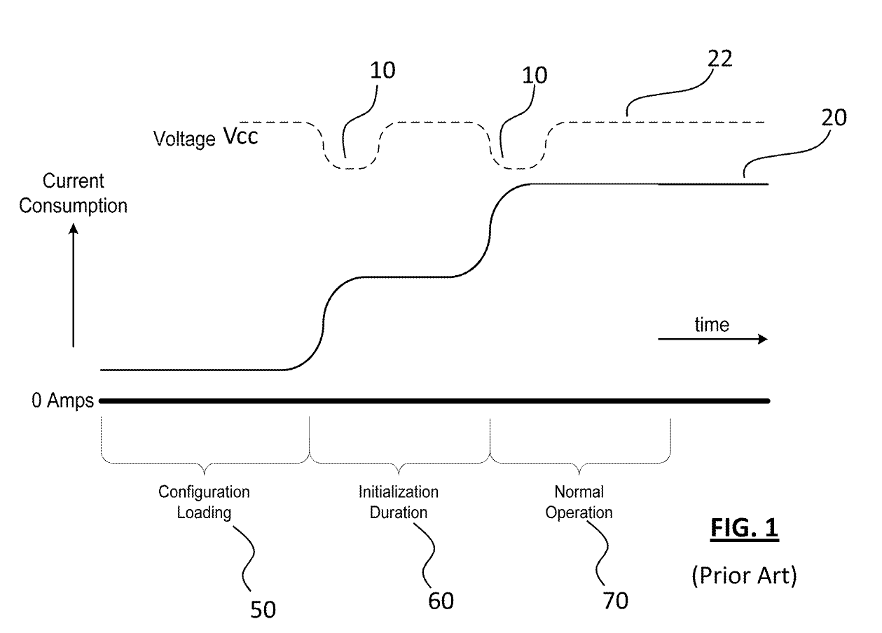

FIG. 2 graphically shows an example of a method of ramping a high-speed clock in an integrated circuit in accordance with the present disclosure.

FIG. 3 schematically shows an example of staged signals for modulating a high speed clock in a semiconductor integrated circuit device.

FIG. 4 schematically shows an example of a circuit for modulating a high-speed clock to control power surge in an integrated circuit.

In the drawings, identical reference numbers identify similar elements or components. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn, are not intended to convey any information regarding the actual shape of the particular elements, and have been solely selected for ease of recognition in the drawings.

### DETAILED DESCRIPTION OF THE PREFERRED EMBODIMENTS

The following disclosure describes several embodiments and systems for reducing current surge in an integrated circuit. Several features of methods and circuits in accordance with example embodiments of the invention are set forth and described in the Figures. It will be appreciated that methods and circuits in accordance with other example embodiments of the invention can include additional procedures or features different than those shown in Figures. Example embodiments are described herein with respect to FPOA devices. However, it will be understood that these examples are for the purpose of illustrating the principals of the invention, and that the invention is not so limited.

Additionally, methods and circuits in accordance with several example embodiments of the invention may not include all of the features shown in these Figures. Throughout the Figures, like reference numbers refer to similar or identical components or procedures.

Unless the context requires otherwise, throughout the specification and claims which follow, the word “comprise” and variations thereof, such as, “comprises” and “comprising” are to be construed in an open, inclusive sense that is as “including, but not limited to.”

Reference throughout this specification to “one example” or “an example embodiment,” “one embodiment,” “an embodiment” or various combinations of these terms means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

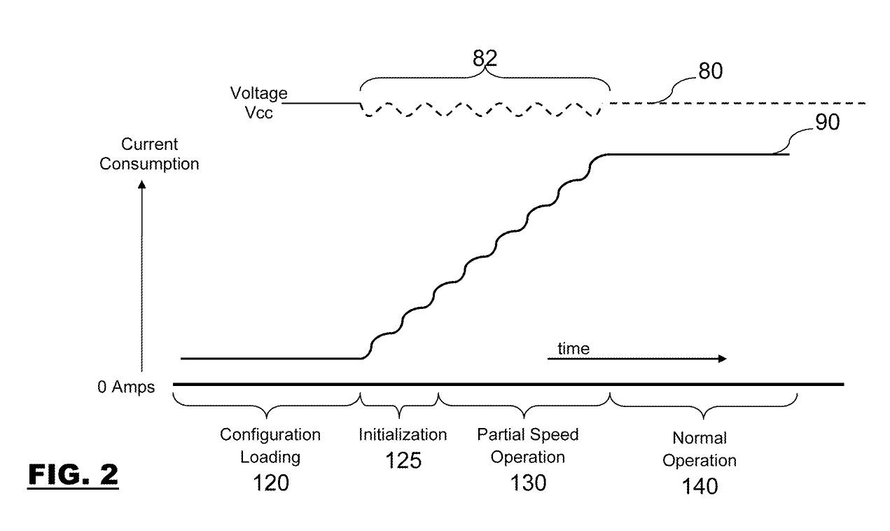

Referring now to FIG. 2 an example of a method of ramping a high-speed clock in an integrated circuit in accordance with the present disclosure is graphically shown. There shown is a current consumption curve 90 exhibiting a method of ramping current as a function of time during a transition from a holdstate to an operational state in order to reduce power supply voltage drops. The transition from the holdstate to operational state may be segmented into multiple phases including a configuration loading phase 120, an initialization phase 125, a partial speed operation phase 130 and a normal operation phase 140. Also shown as a function of time is a voltage power supply curve 80 showing concomitant minimal effects of the ramping current on the power supply voltage, V_{cc}, when transitioning from the holdstate to the operational state. During the switch from the holdstate to the operational state, the voltage V_{cc} is affected by a series of small pulses 82.

In operation, the configuration loading phase 120 the ramping period may be configured, as by a user for example, with no core clock gated to other operational circuits. After the configuration loading phase 120, clock operation is started and current begins ramping up during the initialization phase 125. The initialization phase spans a time period that is proportionally related to the ramped core clock rate and that may be varied depending on the integrated circuits particular application. As detailed further below, a user can configure a release initialization value at a partial core clock rate suitable for starting selected logic circuits before full clock rate is reached. When the ramped core clock rate meets or exceeds the user-configured release initialization value, then partial speed operation begins in the partial speed operation phase 130. When the core clock is ramped up to its full rate of speed the normal operation phase 140 begins. A return signal may advantageously be provided signaling the integrated circuit that full operational speed has been attained.

In contrast to the prior art, the current is ramped during the partial speed operation period 130 by modulating device clock toggling. The resulting series of small pulses 82 on the voltage supply line are significantly smaller than in previous devices and sufficiently limited in amplitude so as to maintain data integrity and power supply performance at an acceptable level. The ramped current rises in a controlled manner from about 0 amps during configuration loading to the full current value required during normal operation.

Table 1 illustrates one example of transitioning a core clock rate from a holdstate to an operational state. A plurality of M stages of staged signals is separated by a ramp interval. Each of the M stages enables an increasing number of pulses n1 . . . N to be gated to transition the integrated circuit from a holdstate to an operational state when a full duty cycle for the core clock is reached with N out of N pulses being gated. Here M, n1 . . . and N may be any number. The ramp interval may optionally be uniform, configurable or both.

TABLE 1

| Stage # | Pulses enabled |
|---|---|
| Stage 0 | n1 out of N |
| Stage 1 | n2 out of N |
| Stage 2 | n3 out of N |
| Stage 3 | n4 out of N |

.
.
.

| | |
|---|---|
| Stage M | N out of N |

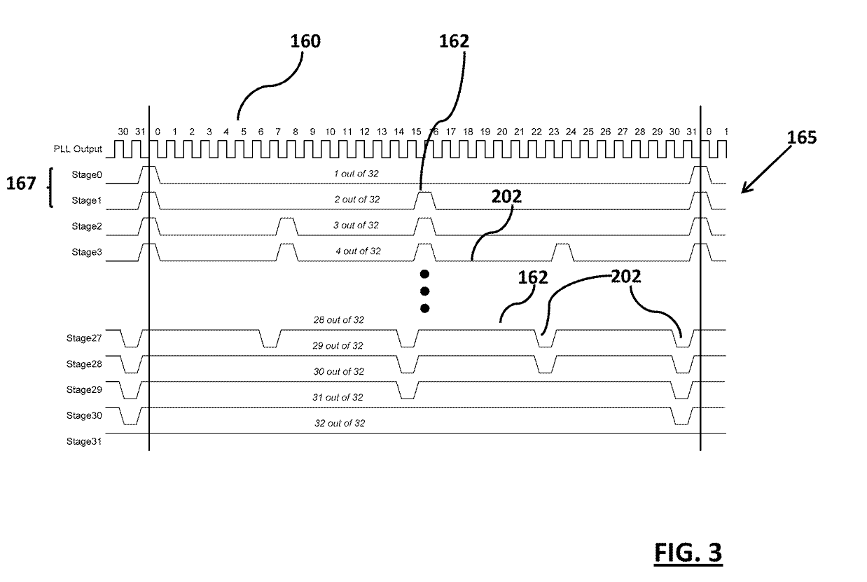

Referring now to FIG. 3, an example of staged signals for modulating a high speed clock in a semiconductor integrated circuit device is schematically shown. A high speed clock output toggling at full speed is shown as, for example, phase locked loop clocking output, PLL 160. A series of holdstate staged signals 165 gate the PLL output 160 to gradually ramp up the device current to operational state values. The series of holdstate staged signals 165 may include N stages. Further, each stage may be configured to gate increasing numbers of core clock pulses until the full core clock rate is reached.

Although shown as Stage0 through Stage31 in the example of FIG. 3, any number of stages N suitable to control power surges may be used and the invention is not limited to N=32 stages or a 32 pulse duty cycle. Each stage is separated by a ramp period 167. In the example of FIG. 3, a first gating signal, stage0, includes a gating pulse 162 that gates a single clocking pulse from the PLL output 160, a second gating signal, stage1, includes two gating pulses 162 for gating two PLL clocking pulses, a third gating signal, stage2, includes three gating pulses 162 for gating three PLL clocking pulses and so on until the total number of PLL clocking pulses required for the operational state have been gated through to the integrated circuit device. During intervals 202 between the gating pulses 162 PLL clocking pulses are not gated. The integrated circuit current is proportional to the number of clocking pulses generated by the PLL as a holdstate or core clock gate signal so that, for example, the first gating pulse results in a current rise of about 1/32nd of full operational current, the second gating pulse allows a current rise to about 2/32nds and so on until the current gradually reaches 100% of the operational current at stage31 when all clock pulses are gated.

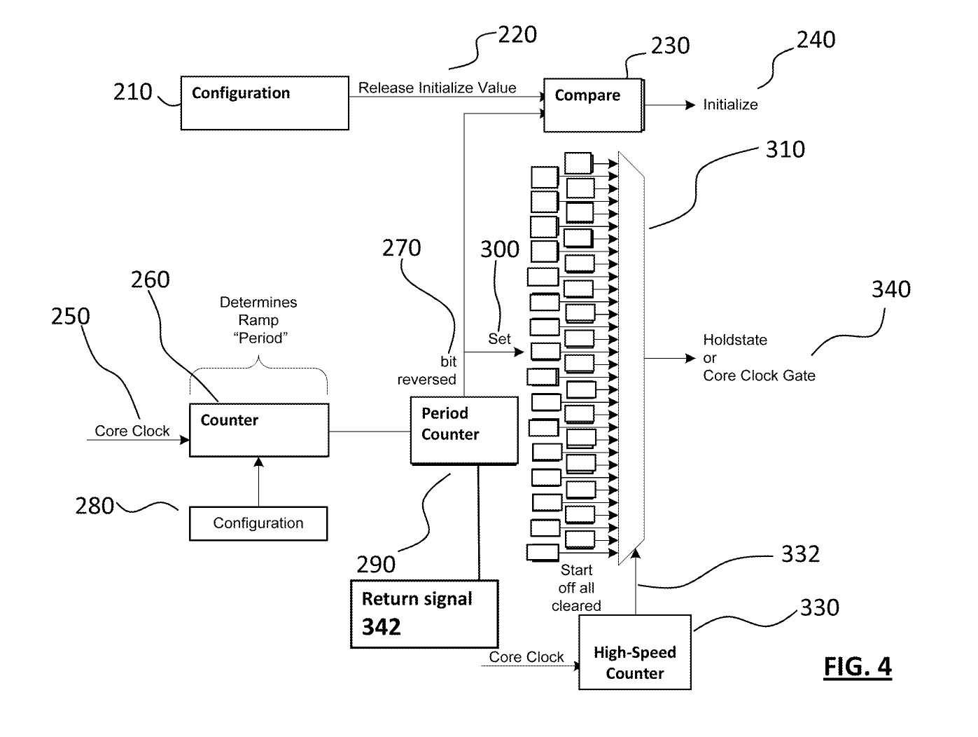

Referring now to FIG. 4, an example of a circuit for ramping a high-speed clock to reduce current surge in an integrated circuit is schematically shown. A core clock 250 transmits a clocking signal to a counter 260 that is configured by a first configuration circuit 280. The counter 260 sends a counter output to a ramp period counter 290. The ramp period counter 290 transmits a bit reversed signal 270. The core clock 250 also clocks a high speed counter 330, where the high-speed counter 330 generates a multiplexer clocking signal 332. A multiplexer 310 includes a plurality of pin inputs for receiving and responding to a set signal 300 from the period counter 290. The multiplexer 310 supplies the system clock, initially gating a holdstate modulated clock and ramping up to a full core clock rate.

A second configuration circuit 210 releases an initialization value 220 to a first input of a comparator 230. The comparator 230 coupled to receive the bit reversed signal 270 for comparison to the initialization value. The initialization value is advantageously configured in proportion to a current value at which the integrated circuit starts running applications in a soft start mode, that is, where the current is large enough to enable initial applications like start up logic, but before the current reaches full operational current flow. When the initialization value is reached, the comparator deactivates an “Initialize” signal 240. The Initialize signal operates as a reset signal. While active, the majority of the circuitry throughout the chip is held stable. By providing configuration information identifying which of the N stages causes the Initialize signal to deactivate allows tradeoffs between power surge limitations versus operation limitations due to the clock not operating at full speed.

In one example embodiment the core counter 260 may be any suitable counter like a 16-bit binary counter, a Linear Feedback Shift Register (LFSR) or equivalent device. The first configuration circuit 280 is adapted to be configured by a user according to a desired ramping period. The period counter 290 and the high speed counter 330 may be any suitable digital counters or equivalent devices. Other components, such as the comparator 230, and multiplexer 310 may be constructed in accordance with known engineering principles.

Having described the apparatus for ramping a high-speed clock to reduce current surge, a description of the operation of an example embodiment is now provided to facilitate understanding of the disclosure. In operation, the first configuration circuit 280 is loaded to configure the counter 260 to determine the ramp period of each of a plurality of modulation intervals or stages. In one example, N stages may be modulated by a uniform ramping period that skips, for example, at least one core clock pulse between each gating stage, where the gating stages allow progressively more core clock pulses to be transmitted to the core clock gate to return the integrated circuit device to operational status as discussed above. The output from the counter 260 is transmitted to the period counter 290. The multiplexer 310 starts with all gating inputs cleared, corresponding to no clock pulses being gated. The period counter 290, through set signal 300 progressively sets gating bits in multiplexer 310 in response to the period count. The output 270 of the period counter is also provided to the comparator 230, where the comparator 230 provides an initialization signal at a user-configured initialization current level that is usually smaller than the operational current level. The high-speed counter 330 continually strobes the multiplexer 310 to allow the multiplexer to transmit clocking pulses corresponding to the number of gated clock pulses. As indicated in Table 1, as each bit of the multiplexer is enabled, the clock rate advances from a fraction of the core clock duty cycle up to 100% at the full core clock rate. The rise in current follows the clock modulation and ramps up in proportion to the number of bits enabled in the multiplexer 310.

In this way, the circuit generates a core clock speed using a multiplexer and configurable modulation period using user-configurable uniform skip periods. Thus the above-described method and circuit provides superior implementation from the standpoint of modulating the clock rate and, as a result, ramps up the current and resultant power, more uniformly. In a one useful embodiment the circuit also provides a return signal that informs the FPOA device that full speed operation has been attained.

The invention has been described herein in considerable detail in order to comply with the Patent Statutes and to provide those skilled in the art with the information needed to apply the novel principles of the present invention, and to construct and use such exemplary and specialized components as are required. However, it is to be understood that the invention may be carried out by specifically different equipment, and devices, and that various modifications, both as to the equipment details and operating procedures, may be accomplished without departing from the true spirit and scope of the present invention.

What is claimed is:

1. A method for ramping a high-speed clock to control power surge in an integrated circuit when transitioning from a low power holdstate to an operational state, the integrated circuit including selected logic circuits adapted to be maintained in the holdstate, the method comprising:
transmitting a core clock signal including a plurality of core clock pulses; and
gating the core clock signal with a ramping signal, where the ramping signal includes a series of staged signals having gating pulses, each staged signal being separated by a ramp interval, where the series of staged signals successively enables increasing numbers of clocking pulses from the core clock signal to be transmitted to a holdstate output until a predetermined operational core clock frequency is transmitted to the holdstate output bringing the integrated circuit to the operational state.

2. The method of claim 1 wherein the integrated circuit operation transitions from the holdstate to the operational state through a configuration loading phase with no core clock signal gated, followed by an initialization phase wherein clock operation is started, then a partial speed operation phase when the ramped core clock rate meets or exceeds a user-configured release initialization value, and reaches an operation phase when the core clock is ramped up to its full rate of speed.

3. The method of claim 1 wherein the ramp interval comprises a configurable ramp interval.

4. The method of claim 1 wherein the ramp interval comprises a uniform ramp interval.

5. The method of claim 1 further comprising providing a return signal indication when the predetermined operational clock frequency is attained.

6. The method of claim 1 wherein the increasing numbers of enabled clocking pulses are ramped up by at least one pulse for each successive stage of the series of staged signals.

7. The method of claim 1 wherein the incrementally increasing numbers of clocking pulses are ramped up from a single pulse to full rate core clock speed.

8. The circuit of claim 5 wherein the ramp interval comprises an interval spanning one or more core clock duty cycles.

9. The method of claim 1 further comprising:
continuously comparing the number of enabled clocking pulses during each successive gating pulse with a pre-configured initialization value; and
soft-starting the selected logic circuits when the number of enabled clocking pulses during one of the successive gating pulses reaches the pre-configured initialization value.

10. A circuit for ramping a high-speed clock to control power surge in an integrated circuit during a transition from a holdstate to an operational state, the integrated circuit including selected logic circuits adapted to be maintained in the holdstate, the circuit comprising:
a core clock that transmits a core clock signal;
a first counter coupled to the core clock signal;
a first configuration circuit coupled to the first counter, where the first configuration circuit configures the first counter to transmit a first counter output including a ramp period;
a second counter coupled to the first counter output, where the second counter transmits a ramping signal in response to the first counter output;
a high speed counter also coupled to the core clock signal; and
a multiplexer coupled to the high speed counter, where the high-speed counter generates a multiplexer pin input activation signal, where the multiplexer includes a holdstate output and where the ramping signal includes a series of staged signals having gating pulses, each staged signal being separated by a ramp interval, where the series of staged signals successively enables increasing numbers of clocking pulses from the core clock signal to be transmitted to the holdstate output until a predetermined operational clock frequency is transmitted to the holdstate output bringing the integrated circuit up to run in the operational state.

11. The circuit of claim 10 further comprising a second configuration circuit that transmits an initialization value to a first input of a comparator, where the comparator has a second input coupled to receive the ramping signal for comparison to the initialization value, where the initialization value is configured in proportion to a current value at which the integrated circuit starts running selected logic circuits in a soft start mode.

12. The circuit of claim 11 wherein the ramping signal comprises a plurality of ramp intervals.

13. The circuit of claim 11 wherein the ramp interval comprises an interval spanning one or more core clock duty cycles.

14. The circuit of claim 10 wherein the integrated circuit comprises a field-programmable object array device.

15. A circuit for ramping a high-speed clock to control power surge in an integrated circuit including selected logic circuits adapted to be maintained in a holdstate, the circuit comprising:
means for transmitting a core clock signal including a plurality of core clock pulses;
means, coupled to the core clock signal transmitting means, for gating the core clock signal with a ramping signal, where the ramping signal includes a series of staged signals having gating pulses, each staged signal being separated by a ramp interval, where the series of staged signals successively enables increasing numbers of clocking pulses from the core clock signal to be transmitted to a holdstate output until a predetermined operational clock frequency is transmitted to the holdstate output;
means, coupled to the gating means, for continuously comparing the number of enabled clocking pulses during each successive gating pulse with a pre-configured initialization value; and
wherein the comparing means provides an initialize signal for soft-starting the selected logic circuits when the number of enabled clocking pulses during one of the successive gating pulses reaches the pre-configured initialization value.

16. The circuit of claim 15 further comprising means, coupled to the holdstate output, for providing a return signal indication when the predetermined operational clock frequency is attained.

17. The circuit of claim 16 wherein the initial stage of the series of staged signals gates a single clock pulse.

18. The circuit of claim 16 wherein the enabled incrementally increasing numbers of clocking pulses are increased by at least one pulse for each successive stage of the series of staged signals.

19. The circuit of claim 16 wherein the integrated circuit comprises a field-programmable object array device.

20. The method of claim 16 wherein the ramp interval comprises a configurable ramp interval.

21. The method of claim 16 wherein the ramp interval comprises a uniform ramp interval.
